(19) United States
(12) Patent Application Publication
(10) Pub. No.: US 2025/0358965 A1
(43) Pub. Date: Nov. 20, 2025

(54) COOLING SYSTEM FOR THE LIQUID IMMERSION COOLING OF ELECTRONIC COMPONENTS

(71) Applicant: Wieland-Werke AG, Ulm (DE)

(72) Inventors: Achim GOTTERBARM, Dornstadt (DE); Harald GAIBLER, Rottenacker (DE); Philipp HOFMANN, Weissenhorn (DE); Verena OBST, Neu-Ulm (DE); Michael SCHEUSS, Köln (DE)

(21) Appl. No.: 18/865,796

(22) PCT Filed: May 17, 2023
(86) PCT No.: PCT/EP2023/000029

§ 371 Date: Nov. 14, 2024

(30) Foreign Application Priority Data
Jun. 20, 2022 (DE) 10 2022 002 216.8

(51) Int. Cl. H05K 7/20

(52) U.S. Cl. CPC H05K 7/203

(57) ABSTRACT

Cooling system for the liquid immersion cooling of electronic components, including a container with an interior fillable with two-phase heat transfer fluid, into which container electronic components can be immersed. The container has a gas space above a surface of the heat transfer fluid, and a heat exchanger device is disposed in the gas space for forming liquid heat transfer fluid. The heat exchanger device has at least one tube bundle including a plurality of heat exchanger tubes fixed in at least one tube sheet. The at least one tube sheet of the at least one tube bundle is formed as part of a container wall of the container.

The invention relates to a cooling system for the liquid immersion cooling of electronic components according to the preamble of claim 1.

Cooling systems for liquid immersion cooling, for example as two-phase immersion cooling systems, are an active cooling solution for electronic components which generate a significant amount of heat during operation. When the components are immersed into a two-phase heat transfer fluid, which generally has a low boiling point, the heat generated by the electronic component can vaporize the surrounding liquid heat transfer fluid, whereby heat is dissipated from the electronic component. A condenser device liquefies the gaseous heat transfer fluid which is then returned into the reservoir for cooling.

A two-phase immersion cooling system with a cooling basin is disclosed in the publication U.S. Pat. No. 10,512,192 B2. A condensation chamber, in which the gaseous fluid produced during the cooling process is condensed, is connected to the liquid fluid in the cooling basin. A vapor redirection structure is arranged above the heat-generating electronic components which are located inside the cooling medium in the cooling basin. The vaporized fluid is conducted by means of the vapor redirection structure into the condensation chamber for liquefaction. The condensation chamber is located completely inside the cooling basin. Only the supply lines and discharge lines of the fluid located in the cooling tubes are passed through the cooling basin wall.

In this context, a cooling system for computer components is disclosed in the publication U.S. Pat. No. 10,477,726 B1. A heat-conducting dielectric heat transfer fluid in the liquid and gaseous phase, which has a boiling point of below 80° C. at atmospheric pressure, is located in a pressure-controlled container. Computer components, which are at least partially immersed in the liquid phase of the heat transfer fluid, are arranged in the container. The dielectric gas-phase fluid, which has been vaporized by the heat generated by the computer components, is condensed by means of a condenser to form dielectric liquid-phase fluid. The internal pressure is reduced to 650 hPa in the interior of the pressure-controlled container. The user can influence the temperature at which the dielectric liquid is vaporized by controlling the pressure in the container in which the system operates. This enables an increased cooling capacity to be achieved. The operation of a computer system inside a pressure-controlled container at an operating pressure which deviates from the ambient pressure generally requires a structural adaptation of the system as a whole.

The object of the invention is to develop a cooling system for the liquid immersion cooling of electronic components relative to a heat exchanger device.

The invention is described by the features of claim 1. The further dependent claims relate to advantageous embodiments and developments of the invention.

The invention encompasses a cooling system for the liquid immersion cooling of electronic components. The cooling system comprises a container having a container wall which can be filled with two-phase heat transfer fluid into which electronic components can be immersed in the liquid phase thereof. The container has a gas space above the surface of the liquid heat transfer fluid. The cooling system also has a heat exchanger device in the gas space of the container for the purposes of forming liquid heat transfer fluid. The heat exchanger device in the gas space consists of at least one tube bundle of a plurality of heat exchanger tubes which are arranged relative to one another and which are fixed in at least one tube sheet. The at least one tube sheet of a tube bundle is formed as part of the container wall.

The two-phase heat transfer fluid, also denoted as coolant, represents the external fluid located in the container, the electronic components being immersed in the liquid component thereof. The internal fluid located in the heat exchanger tubes is a single-phase heat transfer medium, for example process water.

A tube bundle can have a plurality of heat exchanger tubes arranged parallel to one another with two tube sheets at the ends. A tube sheet is particularly suitable when using tubes running in a U-shaped manner and in which both the supply line and the discharge line of the internal fluid are located on the tube sheet. Different arrangements of spiral tubes can also be used in a tube bundle.

The arrangement of the tube bundles or the heat exchanger tubes in the container can be implemented symmetrically and also asymmetrically or along inclines relative to the container wall.

The tube sheet fixes the position and the spacings of the heat exchanger tubes in the tube bundle. The tube sheet and heat exchanger tubes form a separate module which is connected to the container wall.

The tube sheet and container wall can comprise a fixed or even releasable connection. In both cases, the tube sheet stabilizes the surrounding container wall relative to deformation. In particular during operation, the tube sheet absorbs at least one portion of the deformation forces which are produced by negative pressure or positive pressure on the surrounding container wall. The tube sheet is designed to be more stable relative to the container wall and as a result acts as a stabilization of the container relative to deformation. The modular design of the tube bundle as such already has a stable structure relative to mechanical influences. Releasable connections to the container wall also permit a particularly simple exchange of the modules. Specifically, a simple exchange of modules having a different cooling capacity, together with a variable number of heat exchanger tubes, permits a corresponding flexibility in the design of the cooling system. In particular, this achieves a structure mechanically stabilizing the container.

In the container the electronic components are arranged in a bath of liquid heat transfer fluid in a manner which is suitable for cooling, said electronic components being cooled by the vaporization of the liquid fluid. The proportion of non-condensable gases can be removed from the system before and/or during start-up. A plurality of separate tube bundles, which form the heat exchanger device as a whole, can also be arranged so as to be distributed in the gas space of the container.

In the embodiment according to the invention, the computing components and immersion cooling devices and the associated power supplies, network connections, wired connections and the like, can be arranged in the container which has an internal pressure deviating from the ambient pressure during operation.

In this context it is also advantageous to combine power, water, vacuum and network connections in a bundle of lines in order to minimize the lead-throughs into the container and in order to reduce the risk of leakages, in particular when the system is under a vacuum or positive pressure during operation.

In advantageous embodiments, during operation the container is held at up to 200 hPa less than the atmospheric ambient pressure, which contributes to reducing the boiling point of the two-phase heat transfer fluid and thereby to reducing the operating temperature of the computer chip and other components. In several particular embodiments, the pressure-controlled container can have an even lower pressure of up to 500 hPa below the ambient pressure. With increasingly lower pressures, the structural measures according to the invention on the container wall are particularly advantageous for compensating for pressure differences.

Embodiments according to the invention of the cooling system comprise a container which is designed such that a two-phase liquid immersion cooling system is used. The container contains a basin of dielectric cooling fluid, and a heat exchanger device for condensing the dielectric fluid from the gaseous phase to a liquid. It is also possible to arrange devices for holding computer components and for distributing power from the power supply system to the devices and components which are located inside the container.

It goes without saying that a plurality of specialized connections have to be used in order to operate a computer system inside a container which is held, for example, at a negative pressure. Several embodiments of the system according to the invention can use a series of fiber-optic interfaces which enable a connectivity to the container, and to distribute the fibers to the different holding devices for the electronic components. Several embodiments of the container can contain sensors for safe operation. These sensors can comprise temperature sensors, fluid level sensors, pressure sensors, position sensors, electrical sensors and/or cameras in order to ensure and to automate the operation of the system.

These systems can comprise, for example, pressure sensors inside the pressure-controlled container which monitor the pressure in order to ensure that no substantial leakages are present. Gas sensors which are arranged on the outer face of the pressure-controlled container and detect the presence of possibly present dielectric vapor which escapes from the pressure-controlled container can also.

The cooling system can also advantageously have a control device which is designed to control the operation of the fluid circulation, for example, as a function of the temperature of the two-phase heat transfer fluid and the pressure conditions in the container.

Advantageous embodiments of the cooling system according to the invention can be an external frame which stabilizes the container and which can be designed from metal profiles in the form of a frame structure and encloses and supports the container. The frame structure can be an open design which comprises a cover, side walls and doors for simple access during operation and for maintenance operations. This permits access to the cooling system at on-site locations.

In an advantageous embodiment, a mounting system can be set up by which the electronic components can be transported from the lock device to the operating position for the exchange thereof. A mounting system can consist of robot arms or linear drive devices. With a suitable configuration of the device, an exchange of the components can be carried out via a fully automatic mounting system. Alternatively, gloves can also be arranged at suitable container openings for an exchange of the electronic components from the lock device to the operating position. This enables mounting by manual access into the interior of the container.

In a preferred embodiment of the invention, the container wall can have at least one recess as a passage point for the heat exchanger tubes, wherein the recess can be covered in a fluid-tight manner by the at least one tube sheet. In practice, the passage point in the surface is configured to be slightly smaller than the tube sheet surface and adapted in terms of shape such that the tube sheet completely covers the recess and slightly overlaps the container wall. This facilitates the connection of the tube sheet and the adjoining container wall to one another as joined parts. As an alternative to an extensive recess, a plurality of recesses could also be respectively present with a surface through which each of the heat exchanger tubes is individually passed. The tube sheet is then arranged on the inner or outer face of the container wall. A recess, however, can also correspond exactly to the contour of a tube sheet which in this case then exactly fits into the container wall.

Advantageously, the tube sheet can be a planar metallic plate with lead-throughs for the heat exchanger tubes, wherein the thickness of the plate corresponds to at least three times the thickness of the remaining container wall. The material and the thickness of the tube sheet is substantially dictated by the supporting function and stability of the structure. Thus steel is suitable as a material, for example, the plate thickness thereof being designed to be sufficiently great for increasing the stability.

In an advantageous embodiment of the invention, the tube sheet can be welded to the container wall. Relative to other joining methods, a welded connection represents a particularly stable material connection.

In an advantageous embodiment of the invention, a connection box for distributing, diverting or collecting the single-phase heat transfer medium, which can be passed through the heat exchanger tubes, can be arranged on the at least one tube sheet on the outer face of the container. In the case of a plurality of tube sheets or passage points of the heat exchanger tubes through the container wall, in each case further connection boxes can be arranged for the single-phase heat transfer medium located in the heat exchanger tubes. The supply lines or the discharge lines for the internal fluid branch off from these connection boxes which are also denoted as water boxes.

Advantageously, the connection box can be removably connected to the tube sheet. Thus it is possible to access the heat exchanger tubes in the tube bundle in a simple manner for maintenance purposes or for the exchange thereof. The fixing points can also be located on the stable tube sheet by means of screw connections and sealing surfaces, since the greater material thickness thereof relative to the container wall requires a more stable connection.

The heat exchanger tubes can be designed as smooth tubes or even as finned tubes. In an advantageous embodiment, the heat exchanger tubes can have integral fins formed on the tube outer face and circulating in a helical manner and a channel can be configured between the fins.

Such finned tubes are produced from smooth tubes which have been subjected to a forming process. Finned tubes are suitable, in particular, as components in highly efficient, compact and exceptionally stable heat exchangers with a high heat transfer coefficient. The tube surfaces are optimized to the specific heat transfer needs of the application. A wide selection of materials which include copper, copper alloys, steels or titanium, ensures that material which is suitable for different needs is available for the respective requirements, in particular relative to the durability and deformability.

Advantageously, the heat exchanger tubes can be connected in the lead-throughs of the tube sheet by widening, wherein a gas-tight and pressure-resistant connection is formed. In particular, the above-mentioned selection of materials are generally ductile metals or metal alloys which permit the widening of the heat exchanger tubes for connecting to the tube sheet. Such mechanically produced connections represent a resilient and stable joint.

Advantageously, the heat exchanger tubes can be soldered, adhesively bonded or welded into the tube sheet. Due to their material connection, such connections have proved to be both gas-tight and sufficiently mechanically stable in order to generate a compact modular tube bundle.

Advantageously, a tube bundle consisting of heat exchanger tubes can have two tube sheets which are connected at the ends at opposing points to the remaining container wall at recesses as passage points. Each tube sheet is then connected to the container wall at each passage point for the heat exchanger tubes. The container wall is stabilized by each tube sheet thus positioned.

In an advantageous embodiment of the invention, the heat exchanger tubes can be arranged in the container in a straight line between the two tube sheets at the ends. In this manner, the tube sheet and the arrangement of the heat exchanger tubes connected thereto are configured to be optimized in terms of flow for the fluid flowing in the interior.

Such tube bundles preferably run in the longitudinal direction on two longitudinal sides of the container in the vicinity of the inner container wall over the entire length thereof. Thus the liquid heat transfer fluid in the vicinity of the container wall can flow back as condensate into the reservoir. The gas flow which is formed in the cooling process on the electronic components is not influenced or only slightly influenced in these side regions. To this end, the container can already have a shape which is correspondingly adapted in terms of flow technology to the fluid flow of the heat transfer fluid.

Advantageously, the container can be designed as a pressurized container which can be operated at a negative pressure and/or positive pressure. A greater cooling capacity can be achieved by controlling the pressure in the container at which the system operates. An important contribution to the structural adaptation of the system as a whole can be ensured by the mechanical stabilizing of the solution according to the invention, by the arrangement of tube bundles on the container wall.

In an advantageous embodiment of the invention, fluid baffles can be arranged for an optimized drainage behavior of the condensate or for distributing gaseous heat transfer fluid. Such additional baffles lead to an optimized drainage behavior for returning the condensate. The vapor distribution of the gaseous heat transfer fluid in the cooling process can thus be advantageously influenced and thus the flow of the two-phase heat transfer fluid in the vapor phase optimized, in order to increase the rate and efficiency of the condensation.

Advantageously, additional reinforcing devices can be arranged starting from the tube bundle, said additional reinforcing devices being guided as far as the container wall and stabilizing this container relative to static and dynamic loads. To this end, the additional reinforcing of the cooling system is substantially arranged in the vicinity of the sealing surfaces which divert the force in an optimized manner in the case of static and dynamic loads in the system and which increase the stability and tightness of the entire system.

Advantageously, the reinforcing devices can be arranged starting from the tube sheet. Due to the stability of the entire tube bundle, the tube sheet already represents a suitable location for the take-up and transfer of forces.

Exemplary embodiments of the invention are explained in more detail by way of the schematic drawings, in which:

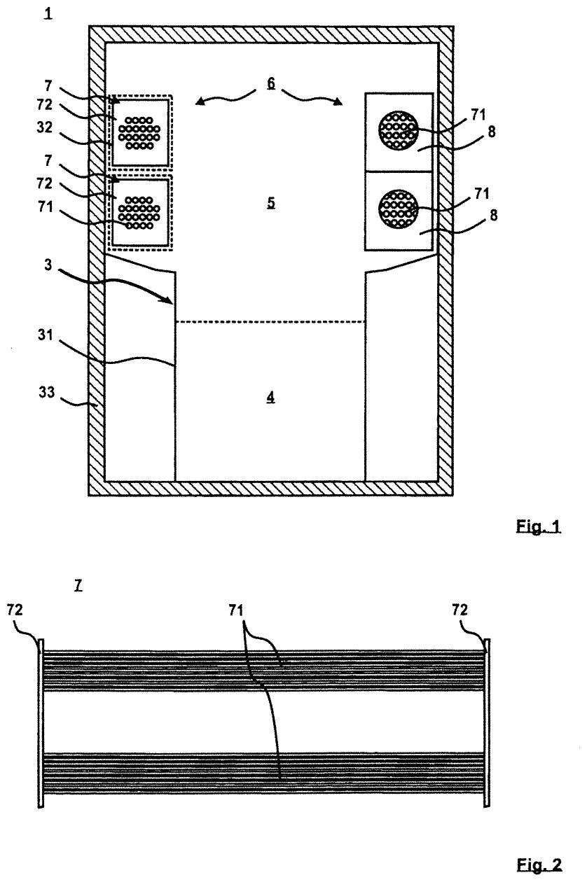

FIG. 1 shows a schematic front view of a cooling system,

FIG. 2 shows a schematic view of a tube bundle,

FIG. 3 shows a schematic side view of a cooling system, and

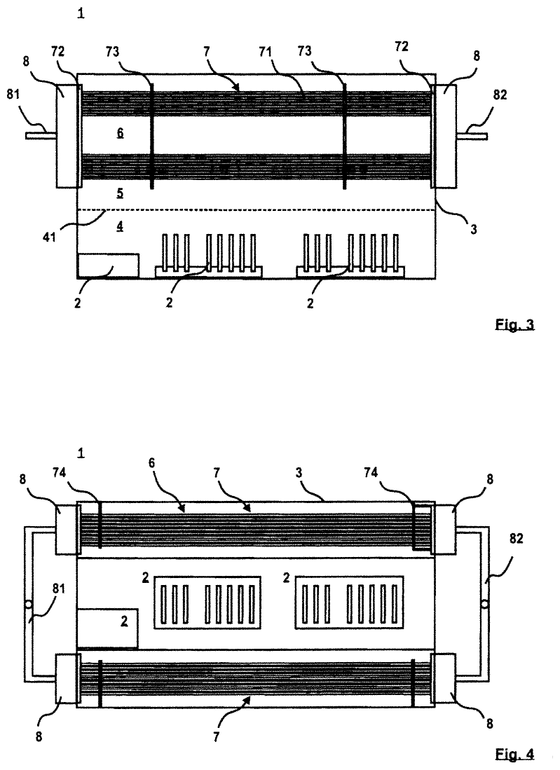

FIG. 4 shows a schematic plan view of a cooling system with a view into the container.

Parts which correspond to one an other are provided in all of the figures with the same reference signs.

FIG. 1 shows a schematic front view of a cooling system 1 for the liquid immersion cooling of electronic components. The cooling system 1 comprises a container 3 with a container wall 31 which can be filled in the interior with a two-phase heat transfer fluid. The two-phase heat transfer fluid represents the external fluid located in the container 3, with a liquid heat transfer fluid component 4 in which the electronic components are immersed and a gaseous heat transfer fluid component 5. In the container 3, a heat exchanger device 6 is arranged in the gas space 5 of the container 3 for forming liquid heat transfer fluid 4.

In this advantageous embodiment, the heat exchanger device 6 in the gas space 5 consists of four tube bundles 7 with in each case a plurality of heat exchanger tubes 71 arranged in parallel with one another. The heat exchanger tubes 71 are fixed in tube sheets 72. The at least one tube sheet 72 of a tube bundle 7 is configured as part of the container wall 3 on the front face. In the two tube bundles 7 visible in the left-hand part of the image in FIG. 1, the region of the tube sheet 72 which overlaps relative to the recess 32 is also illustrated (dashed contour line). Thus the tube sheet 72 completely covers the recess 32. The tube sheet 72 is connected as a joined part to the adjoining container wall 3, for example by a weld seam, not shown in FIG. 1.

In FIG. 1 in the right-hand part of the image, the connection boxes 8 of the heat exchanger device 6 are already mounted on the tube sheets and thus the heat exchanger tubes 71 arranged therebehind are visible only partially through openings. During the operation of the cooling system 1, the internal fluid as a single-phase heat transfer medium is introduced into or discharged from the connection box 8 through these openings. Since water serves as the internal single-phase heat transfer medium in many cases, the connection box 8 is denoted as a water box.

In FIG. 1 in the embodiment shown, the container is slightly tapered in the region of the liquid heat transfer fluid 4 by the container wall 3 projecting inwardly and opening out only in the gas space. The shape of the container 3 is assisted by a metal profile frame 33. As a result, the container 3 is already enclosed by a stabilizing external frame.

FIG. 2 shows a schematic view of a tube bundle 7 of a cooling system. In this embodiment, a tube bundle 7 is formed between two tube sheets 72 consisting of a plurality of heat exchanger tubes 71 closely combined in the upper region and in the lower region. In each case, a metallic plate with lead-throughs for the heat exchanger tubes 72 is arranged at the end as a tube sheet 72. The material and the thickness of the tube sheet 72 ensures a supporting function and the stability of the structure.

FIG. 3 shows a schematic side view of a cooling system 1. The electronic components 2 to be cooled are immersed in the liquid heat transfer fluid 4 below the surface 41 of the liquid fluid. The heat exchanger device 6 is located in the gas space 5.

In this advantageous embodiment, the heat exchanger device 6 in the gas space 5 consists of the tube bundles 7 shown in FIG. 2 with in each case a plurality of heat exchanger tubes 71 which are arranged in parallel with one another and which are fixed in tube sheets 72. The two tube sheets 72 of a tube bundle 7 are fixedly connected on opposing points to the remaining container wall 3 at recesses as passage points. The heat exchanger tubes 71 are arranged in the container in a straight line between the two tube sheets 72 at the ends.

In each case, connection boxes 8 for distributing, diverting or collecting the internal fluid, which can be passed through the heat exchanger tubes 71, are arranged on the tube sheets 72 on the outer face of the container 3.

A first connection box 8 is supplied via a supply line 81 with internal fluid which is distributed therefrom into the heat exchanger tubes 71. The fluid collected in the second connection box 8 is discharged via the discharge line 82 to a cooling device, not shown in FIG. 3.

The fluid baffles 73 arranged on the tube bundle 7 stabilize the entire structure and lead to an optimized drainage behavior for returning the condensate into the liquid heat transfer fluid 4.

In FIG. 4 a schematic plan view of a cooling system 1 is shown with a view into the container 3. Via the supply lines 81, all of the input-side connection boxes 8 are supplied centrally with single-phase heat transfer medium through branches and, after passing through, are collected in the output-side connection boxes 8 and centrally discharged in the discharge line 82.

### LIST OF REFERENCE SIGNS

1 Cooling system
2 Electronic component
3 Container
31 Container wall
32 Recess
33 Metal profile frame
4 Liquid heat transfer fluid
41 Surface of liquid fluid in container
Gaseous heat transfer fluid, gas space
6 Heat exchanger device
7 Tube bundle
71 Heat exchanger tubes
72 Tube sheet
73 Fluid baffle
74 Reinforcing device
8 Connection box, water box
81 Supply line
82 Discharge line

1. A cooling system for the liquid immersion cooling of electronic components, comprising:
a container having a container wall with an interior fillable with two-phase heat transfer fluid into which electronic components can be immersed, wherein the container has a gas space above surface of the liquid heat transfer fluid; and
a heat exchanger device in the gas space of the container for forming liquid heat transfer fluid,
the heat exchanger device in the gas space having at least one tube bundle including a plurality of heat exchanger tubes arranged relative to one another and fixed in at least one tube sheet,
and the at least one tube sheet of a tube bundle is formed as part of the container wall.

2. The cooling system as claimed in claim 1, where the container wall has at least one recess as a passage point for the heat exchanger tubes, wherein the recess is covered in a fluid-tight manner by the at least one tube sheet.

3. The cooling system as claimed in claim 1, wherein the tube sheet is a planar metallic plate with lead-throughs for the heat exchanger tubes and a thickness of the plate corresponds to at least three times a thickness of a remaining part of the container wall.

4. The cooling system as claimed in claim 1, wherein the tube sheet is welded to the container wall.

5. The cooling system as claimed in claim 1, comprising a connection box for distributing, diverting or collecting single-phase heat transfer medium passed through the heat exchanger tubes, the connection box being arranged on the at least one tube sheet on an outer face of the container.

6. The cooling system as claimed in claim 5, wherein the connection box is removably connected to the tube sheet.

7. The cooling system as claimed in claim 1, wherein the heat exchanger tubes each have integral fins formed on a tube outer face and circulating in a helical manner and a channel is configured between the fins.

8. The cooling system as claimed in claim 1, wherein the heat exchanger tubes are connected in lead-throughs of the tube sheet by widening, wherein a gas-tight and pressure-resistant connection is formed.

9. The cooling system as claimed in claim 1, wherein the heat exchanger tubes are soldered, adhesively bonded or welded into the tube sheet.

10. The cooling system as claimed in claim 1, wherein the at least one tube bundle has two tube sheets connected at the ends on opposing points to a remaining part of the container wall at recesses as passage points.

11. The cooling system as claimed in claim 10, wherein the heat exchanger tubes of the at least one tube bundle are arranged in the container in a straight line between the two tube sheets at the ends.

12. The cooling system as claimed in claim 1, wherein the container is configured as a pressurized container operable at a negative pressure and/or a positive pressure.

13. The cooling system as claimed in claim 1, including fluid baffles arranged for an optimized drainage behavior of condensate or for distributing gaseous heat transfer fluid.

14. The cooling system as claimed in claim 1, including additional reinforcing devices arranged starting from the at least one tube bundle, said additional reinforcing devices being guided as far as the container wall and stabilizing the container wall relative to static and dynamic loads.

15. The cooling system as claimed in claim 14, wherein the reinforcing devices are arranged starting from the tube sheet.
